(19) United States
(12) Patent Application Publication
(10) Pub. No.: US 2016/0115589 A1
(43) Pub. Date: Apr. 28, 2016

(54) CARBON-COATED MEMBER AND PRODUCTION METHOD THEREFOR

(71) Applicant: HONDA MOTOR CO., LTD., Tokyo (JP)

(72) Inventors: Koji Kobayashi, Tochigi (JP); Kaoru Kojina, Tochigi (JP); Nobuhiko Yoshimoto, Tochigi (JP); Junya Funatsu, Tochigi (JP)

(21) Appl. No.: 14/888,803

(22) PCT Filed: May 30, 2014
(86) PCT No.: PCT/JP2014/064400

§ 371 Date: Nov. 3, 2015

(30) Foreign Application Priority Data
May 31, 2013 (JP) 2013-116034

(51) Int. Cl. C23C 16/26; C10M 103/02; C23C 16/50

(52) U.S. Cl. CPC C23C 16/26; C23C 16/50; C10M 103/02

(57) ABSTRACT

Provided is a carbon-coated member of which the surface can be simply coated with a DLC coating film to achieve sufficient friction reduction. The carbon-coated member is formed by coating a DLC coating film on an internal sliding part of a cylindrical member. The DLC coating film has a hardness of 3.0 to 10.0 GPa, and a kurtosis Rku of 27.0 or less.

### TECHNICAL FIELD

The present invention relates to a carbon-coated member and a production method thereof.

### BACKGROUND ART

A member having a portion on which another member slides to make a relative movement such as a cylinder block of an internal combustion engine is required to reduce the mechanical loss of the sliding portion in order to achieve reduction in energy consumption and the like. Accordingly, the friction reduction has been investigated. A carbon-coated member having a carbon coating such as a diamond-like carbon coating film (hereinafter abbreviated as DLC coating film, in some cases)on the surface is known for use in the friction reduction (e.g. Patent Literature 1 and 2).

### CITATION LIST

### Patent Literature

Patent Literature 1: Japanese Patent No. 3555844

Patent Literature 2: Japanese Patent No. 4973971

### SUMMARY OF INVENTION

### Technical Problem

The conventional carbon-coated member, however, has a disadvantage that sufficient friction reduction cannot be achieved by simply coating the surface with a carbon coating film such as DLC coating film, while the content of hydrogen, nitrogen or oxygen contained in the DLC coating film is required to be specified and the lubricating oil for use is required to be specified.

An object of the present invention is to eliminate such disadvantage and to provide a carbon-coated member of which the surface can be simply coated with a DLC coating film to achieve sufficient friction reduction.

### Solution to Problem

In order to achieve the object, the carbon-coated member of the present invention includes a cylindrical body and a diamond-like carbon coating film for coating at least a portion of an inner surface of the body on which another member slides, the diamond-like carbon coating film having a hardness in a range of 3.0 to 10.0 GPa, and a kurtosis Rku indicating a surface roughness distribution per area specified in a coating film surface of 27.0 or less.

The carbon-coated member of the present invention achieves friction reduction with a sufficiently reduced coefficient of friction, with the DLC coating film having a hardness in the range of 3.0 to 10.0 GPa, and the kurtosis Rku of 27.0 or less.

With a hardness of the DLC coating film of less than 3.0 GPa, the satisfactory resistance to abrasion required for the surface of the carbon-coated member cannot be obtained, while with a hardness of the DLC coating film of more than 10.0 GPa, the friction reduction of the carbon-coated member cannot be achieved. With the kurtosis Rku of more than 27.0, the friction reduction of the carbon-coated member cannot be achieved.

The carbon-coated member of the present invention includes the DLC coating film having the hardness preferably in a range of 8.0 to 10.0 GPa, in order to achieve friction reduction by further lowering a coefficient of friction. Further, the carbon-coated member of the present invention includes the DLC coating film having the kurtosis Rku of preferably 20.0 or less, more preferably 8.0 or less, in order to achieve the friction reduction by further lowering a coefficient of friction.

Further, the carbon-coated member of the present invention includes the DLC coating film having a surface roughness Rz of preferably 2.7 μm or less. The carbon-coated member of the present invention having the DLC coating film with a surface roughness in the range allows the recesses of irregularities formed on the DLC coating film surface to retain a lubricating oil.

When the temperature of the carbon-coated member of the present invention becomes high, the lubricating oil burns. Accordingly, a surface roughness Rz of the DLC coating film in the carbon-coated member of the present invention is more preferably 2.0 μm or less. The carbon-coated member of the present invention having the DLC coating film with the surface roughness in the range allows the consumption of the lubricating oil to be reduced.

The carbon-coated member of the present invention may be used as, for example, a cylinder block of an internal combustion engine.

A production method of a carbon-coated member of the present invention, the carbon-coated member including a cylindrical body and a diamond-like carbon coating film for coating at least a portion of an inner surface of the body on which another member slides, the diamond-like carbon coating film having a hardness in a range of 8.0 to 10.0 GPa, and a kurtosis Rku indicating a surface roughness distribution per area specified in a diamond-like carbon coating film surface of 27.0 or less, includes the steps of: sealing both end portions of the body to reduce a pressure inside the body to a vacuum level in a range of 1 to 100 Pa; a step of removing foreign matter present on the inner surface of the body; and a step of supplying acetylene gas inside the body at a flow rate in a range of 500 to 4000 sccm while maintaining the vacuum level in a range of 1 to 30 Pa inside the body, to generate plasma to deposit the diamond-like carbon coating film on the inner surface of the body.

According to the production method of the carbon-coated member of the present invention, first the pressure inside the body with both ends sealed is reduced to a vacuum level of 1 to 100 Pa. Subsequently the foreign matter present on the inner surface of the body is removed under the vacuum level.

An expensive device is required for reducing the pressure inside the body to a vacuum level less than 1 Pa, while the foreign matter cannot be removed with a vacuum level more than 100 Pa.

Subsequently acetylene gas is supplied inside the body at a flow rate in the range of 500 to 4000 sccm while maintaining the vacuum level in the range of 1 to 30 Pa inside the body after the removal of the foreign matter, to convert the gas into plasma to deposit the diamond-like carbon coating film on the inner surface of the body. As such the DLC coating film having a hardness in the range of 8.0 to 10.0 GPa and a kurtosis Rku in the range of 27.0 or less can be formed.

An expensive device is required for reducing the pressure inside the body to a vacuum level less than 1 Pa, and the acetylene gas cannot be converted into plasma with a vacuum level of more than 30 Pa.

Beyond the above range of the flow rate of the acetylene gas, the DLC coating film having a hardness and a kurtosis Rku in the ranges cannot be formed.

The production method of the carbon-coated member of the present invention preferably includes a step of supplying a pulse current in a range of 2 to 100 A to the body for a time in a range of 5 to 200 seconds to apply a bias voltage to the body to convert the acetylene gas into plasma.

With the pulse current of less than 2 A supplied for less than 5 seconds, the acetylene gas cannot be converted into plasma in some cases. Further, when the pulse current of more than 100 A supplied for more than 200 seconds, the DLC coating film having a hardness and a kurtosis Rku in the ranges cannot be formed in some cases.

### BRIEF DESCRIPTION OF DRAWINGS

FIG. 1 is a system configuration diagram showing a configuration example of a plasma CVD apparatus for use in the production method of a carbon-coated member of the present invention.

FIG. 2 is a flowchart showing a production method of the carbon-coated member of the present invention.

FIG. 3 is an explanatory view showing a method of calculating a coefficient of friction (COF) based on the digging friction theory.

FIG. 4 is a graph showing the relationship among a hardness and a kurtosis Rku of a DLC coating film, and the coefficient of friction (COF).

### DESCRIPTION OF EMBODIMENTS

In the following, the embodiments of the present invention are described in more detail with reference to the attached drawings.

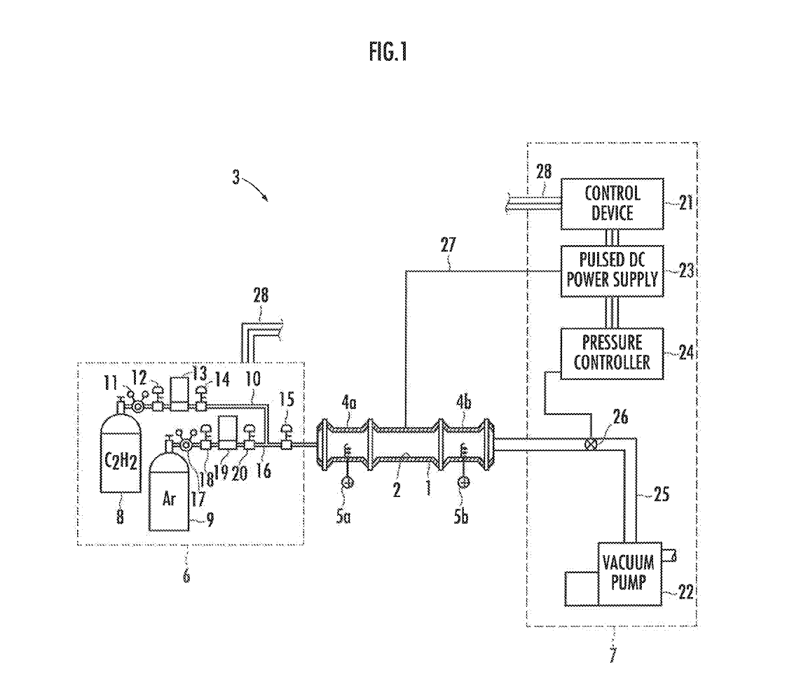

In the present embodiment, a carbon-coated member as cylinder block 1 of which the cross section in the longitudinal direction is shown in FIG. 1 is described as an example.

As shown in FIG. 1, the cylinder block 1 has a cylindrical shape, with an internal cavity part 2 in which a piston (not shown in drawing) slides. The cylinder block 1 is used in a lubricating oil, and the surface of the cavity part 2 is coated with a DLC coating film (not shown in drawing).

The DLC coating film has a hardness in the range of 3.0 to 10.0 GPa, and a kurtosis Rku as statistical numerical value indicating the surface roughness distribution per minute area specified in the coating film surface of 27.0 or less. The DLC coating film has a hardness preferably in the range of 8.0 to 10.0 GPa, and the kurtosis Rku of preferably 20.0 or less, more preferably 8.0 or less.

The hardness is measured as indentation hardness under measurement conditions with a maximum load of 5 mN, using a thin film hardness measuring apparatus (nanoindenter).

The kurtosis Rku is a value obtained by dividing the biquadratic mean of an equation Z(x) representing the roughness curve per standard length in a specified minute area (e.g. a range of 0.4 mm×0.1 mm) of the DLC coating film surface measured by an atomic force microscope (AFM) by the fourth power of root mean square (Rq), which is represented by the following expression (1). The kurtosis Rku is defined in JIS B0601.

$$Rku = \frac{1}{{Rq}^{4}} [ \frac{1}{𝓁 r} {\int }_{0}^{𝓁 r} {Z}^{4} ( x ) d x ] \qquad ( 1 )$$

The DLC coating film has a surface roughness Rz of preferably 2.7 μm or less, more preferably 2.0 μm or less.

The cylinder block 1 having the DLC coating film on the surface of the cavity part 2 can be produced by a plasma CVD apparatus 3 shown in FIG. 1. The plasma CVD apparatus 3 comprises sealing members 4a and 4b which seal both ends of the cavity part 2 in the cylinder block 1, positive electrodes 5a and 5b mounted on the sealing members 4a and 4b, respectively, a gas supply subsystem 6, and a process control subsystem 7.

The sealing members 4a and 4b also serve as insulating materials to separate the positive electrodes 5a and 5b from the cylinder block 1. The positive electrodes 5a and 5b are rod electrodes, which are inserted inside the sealing members 4a and 4b from pore parts (not shown in drawing) disposed at the sealing members 4a and 4b.

The gas supply subsystem 6 comprises an acetylene gas supply container 8 and an argon gas supply container 9. The acetylene gas supply container 8 comprises a conduit 10 connecting to the cavity part 2 of the cylinder block 1 through a pressure gauge 11, a primary-side valve 12 of flow rate control device, a flow rate control device 13, a secondary-side valve 14 of flow rate control device, an open-close valve 15, and a sealing member 4a. On the other hand, the argon gas supply container 9 comprises a conduit 16 connecting to the conduit 10 upstream the open-close valve 15 through a pressure gauge 17, a primary-side valve 18 of flow rate control device, a flow rate control device 19, and a secondary-side valve 20 of flow rate control device.

The process control subsystem 7 comprises a control device 21 composed of a personal computer and the like, a vacuum pump 22 controlled by the control device 21, a pulsed DC power supply 23, and a pressure controller 24. The vacuum pump 22 is connected to the cavity part 2 of the cylinder block 1 through a valve 26 and the sealing member 4b by a conduit 25. The pulsed DC power supply 23 comprises a DC cable 27 which is connected to the outer surface of the cylinder block 1. The pressure controller 24 is electrically connected to an open-close valve 26 provided in the conduit 25.

The control device 21 is connected to the gas supply subsystem 6 through an interface cable 28, controlling the primary-side valve 12 of flow rate control device, the flow rate control device 13, the secondary-side valve 14 of flow rate control device, and the open-close valve 15 which are provided in the conduit 10, and the primary-side valve 18 of flow rate control device, the flow rate control device 19, and the secondary-side valve 20 of flow rate control device which are provided in the conduit 16.

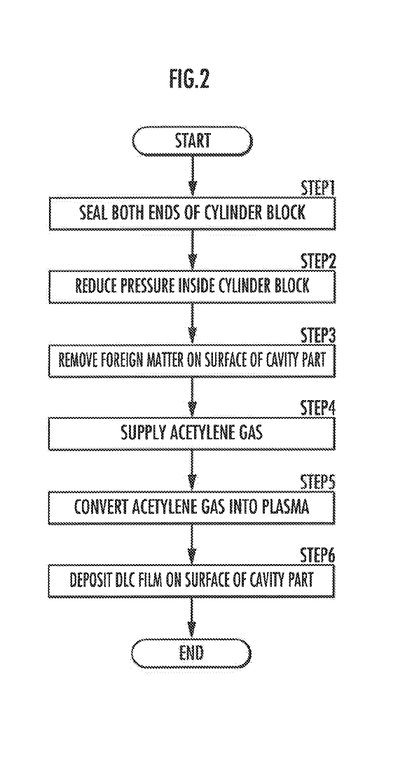

When the DLC coating film is formed on the surface of the cavity part 2 of the cylinder block 1 with the plasma CVD apparatus 3, first of all, as shown in FIG. 2, both ends of the cylinder block 1 are sealed with the sealing members 4a and 4b in STEP 1. Subsequently, the pressure inside the cavity part 2 of the cylinder block 1 is reduced to a predetermined vacuum level in STEP 2. The reduction in pressure is performed by the control device 21, with the open-close valve 26 being opened to a predetermined degree through the pressure controller 24, and with the vacuum pump 22 being activated. Consequently the pressure inside the cavity part 2 is reduced to a vacuum level of, for example, 1 to 100 Pa.

After the pressure inside the cavity part 2 is reduced as described above, foreign matter on the surface of the cavity part 2 is removed for cleaning in STEP 3. In the removal of foreign matter, first, the open-close valve 15 provided in the conduit 12 of the gas supply subsystem 6, and the primary-side valve 18 of flow rate control device and the secondary-side valve 20 of flow rate control device provided in the conduit 16 are opened by the control device 21, and argon gas is supplied to the cavity part 2 from the argon gas supply container 9. The flow rate of the argon gas is adjusted to the range of, for example, from more than 0 sccm to 2000 sccm or less by the flow rate control device 19.

Subsequently, a high-frequency pulsed bias voltage is applied to the cylinder block 1 through the DC cable 27 from the pulsed DC power supply 23 by the control device 21, and thereby argon plasma is generated inside the cavity part 2. On this occasion, the cylinder block 1 functions as a negative electrode, and thus the plasma strikes the surface of the cavity part 2, with the foreign matter on the surface of the cavity part 2 being removed by the plasma, thereby cleaning the surface of the cavity part 2.

Alternatively, the removal of foreign matter on the surface of the cavity part 2 may be performed by supplying oxygen gas instead of the argon gas to generate oxygen plasma instead of the argon plasma. Alternatively, for the removal of foreign matter on the surface of the cavity part 2, a method of chemical gasification using fluorine (C+2F₂→CF₄) may be used.

After completion of cleaning the surface of the cavity part 2, the primary-side valve 12 of flow rate control device and the secondary-side valve 14 of flow rate control device provided in the conduit 10 of the gas supply subsystem 6 are opened by the control device 21 in STEP 4, and thereby acetylene gas is supplied to the cavity part 2 from the acetylene gas supply container 8 together with the argon gas. On this occasion, the flow rate of the acetylene gas is adjusted to the range of, for example, 500 to 4000 sccm by the flow rate control device 13, and the flow rate of the argon gas is adjusted to the range of, for example, 100 to 1000 sccm by the flow rate control device 19.

The open-close valve 26 is opened to a predetermined valve opening position through the pressure controller 24 by the control device 21, and thereby the vacuum level inside the cavity part 2 is maintained at, for example, 5 to 30 Pa.

Subsequently, a pulse current of, for example, 2 to 100 A is applied to the cylinder block 1 for, for example, 5 to 200 seconds through the DC cable 27 from the pulsed DC power supply 23 by the control device 21 in STEP 5. A bias voltage is thereby applied to the cylinder block 1, which functions as a negative electrode as described above, and thereby the acetylene gas is converted into plasma between the cylinder block 1 and the positive electrodes 5a and 5b, mainly generating carbon plasma.

Consequently, the carbon plasma is attracted to the surface of the cavity part 2 of the cylinder block 1 as a negative electrode in STEP 6 to be deposited on the surface. The DLC coating film is thereby formed. The duty cycle of the pulse current is adjusted by the control device 21, such that the acetylene gas and the argon gas are replenished during an off-duty cycle. As a result, it is able to form the DLC coating film on the surface of the cavity part 2 having a uniform thickness.

By the method described above, the DLC coating film can be formed on the surface of the cavity part 2 of the cylinder block 1. The DLC coating film having a hardness in the range of 3.0 to 10.0 GPa, with the kurtosis Rku of 27.0 or less, achieving the friction reduction with a reduced coefficient of friction (COF) of the surface of the cavity part 2. In order to achieve the friction reduction, the DLC coating film has a hardness in the range of, preferably 8.0 to 10.0 GPa, with the kurtosis Rku of preferably 20.0 or less, more preferably 8.0 or less.

The kurtosis Rku increases as the flow rate of the acetylene gas is increased for a bias voltage applied to the cylinder block 1 in the plasma CVD apparatus 3. The film thickness of the DLC coating film becomes more nonuniform as the flow rate of the acetylene gas is decreased for the bias voltage. Accordingly, the flow rate of the acetylene gas is adjusted to the range, and thereby the uniformity of the film thickness of the DLC coating film can be maintained while the kurtosis Rku can be controlled to be in the range.

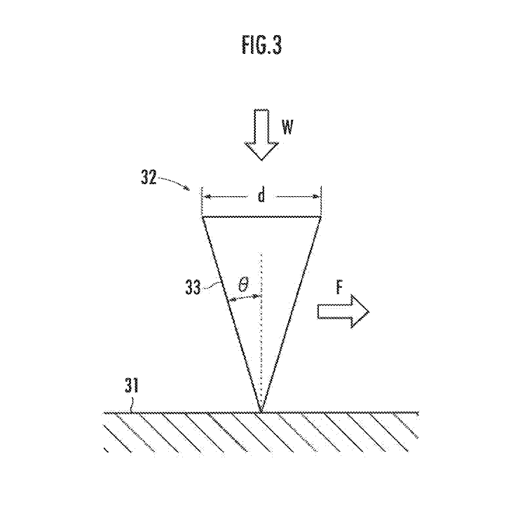

The coefficient of friction (COF) is explained by the digging friction theory shown in FIG. 3. In the digging friction theory, when a projection 32 of the DLC coating film of the cylinder block 1 slides along the surface of a piston 31, the diameter of the projection 32 is represented by d, the angle formed between the side face 33 of the projection 32 and the axis of the projection 32 is represented by θ. On this occasion, with Pf representing the hardness on the piston-side, A1 representing the normal projection area of the projection 32, and n representing the number of the projections 32, a vertical load W is represented by the following Expression (2).

W=A1×Pf=1/8×n×πd²Pf (2)

Further, with A2 representing the projection area in the moving direction of the projection 32, a friction force F is represented by the following Expression (3).

F=A2×Pf=1/4×πd²Pf×cot θ (3)

Hereupon, the coefficient of friction COF is represented by the following Expression (4).

COF=F/W=2 cot θ/n (4)

From the Expression (4), it is obvious that the coefficient of friction COF is proportional to cot θ, and it is assumed that the θ indicates the sharpness of the projection 32. In order to achieve friction reduction, the cylinder block 1 is required to have a coefficient of friction COF of 0.07 or less, preferably 0.05 or less, ideally 0.04 or less.

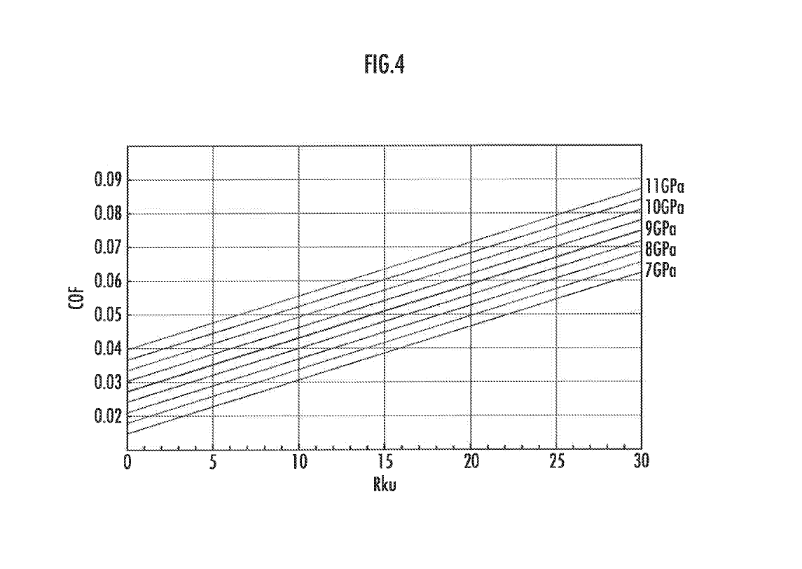

Subsequently, the relationship among the hardness and the kurtosis Rku of a DLC coating film, and the coefficient of friction COF is shown in FIG. 4.

From FIG. 4, it is obvious that the DLC coating film with a hardness in the range of 3.0 to 10.0 GPa, for example, with a hardness of 9.0 GPa, has a coefficient of friction COF of 0.7 or less for a kurtosis Rku of 27.0 or less, a coefficient of friction COF of 0.6 or less for a kurtosis Rku of 20.0 or less, and a coefficient of friction COF of 0.4 or less for a kurtosis Rku of 8.0 or less.

It is also obvious that the DLC coating film with a hardness of 9.5 GPa has a coefficient of friction COF of 0.4 or less for a kurtosis Rku of 7.7 or less.

The cylinder block 1 of the present embodiment has the DLC coating film with a surface roughness Rz of preferably 2.7 μm or less so that a lubricating oil can be retained in the recesses of the irregularities formed on the surface of the DLC coating film. When the temperature becomes high, the lubricating oil bums. Accordingly, it is preferable that the cylinder block 1 has the DLC coating film with a surface roughness Rz of 2.0 μm or less so that the consumption of the lubricating oil can be reduced.

Although the cylinder block 1 is described as an example in the present embodiment, the present invention can be applied to any carbon-coated member in a cylindrical form member having an inner sliding part coated with a DLC coating film

### REFERENCE SIGNS LIST

1 . . . CYLINDER BLOCK
2 . . . CAVITY PART
3 . . . PLASMA CVD APPARATUS
6 . . . GAS SUPPLY SUBSYSTEM
7 . . . PROCESS CONTROL SUBSYSTEM

1. A carbon-coated member comprising:
a cylindrical body and a diamond-like carbon coating film for coating at least a portion of an inner surface of the body on which another member slides;
the diamond-like carbon coating film having a hardness in a range of 3.0 to 10.0 GPa, and a kurtosis Rku indicating a surface roughness distribution per area specified in a coating film surface of 27.0 or less.

2. The carbon-coated member according to claim 1, wherein the hardness of the diamond-like carbon coating film is in a range of 8.0 to 10.0 GPa.

3. The carbon-coated member according to claim 1, wherein the kurtosis Rku of the diamond-like carbon coating film is 20.0 or less.

4. The carbon-coated member according to claim 1, wherein the kurtosis Rku of diamond-like carbon coating film is 8.0 or less.

5. The carbon-coated member according to claim 1, wherein the diamond-like carbon coating film has a surface roughness Rz of 2.7 μm or less.

6. The carbon-coated member according to claim 1, wherein the diamond-like carbon coating film has a surface roughness Rz of 2.0 μm or less.

7. The carbon-coated member according to claim 1 wherein the body is a cylinder block of an internal combustion engine.

8. A method of manufacturing a carbon-coated member including a cylindrical body and a diamond-like carbon coating film for coating at least a portion of an inner surface of the body on which another member slides, the diamond-like carbon coating film having a hardness in a range of 8.0 to 10.0 GPa, and a kurtosis Rku indicating a surface roughness distribution per area specified in a diamond-like carbon coating film surface of 27.0 or less, the method comprising:
a step of sealing both ends of the body to reduce a pressure inside the body to a vacuum level in a range of 1 to 100 Pa;
a step of removing foreign matter present on the inner surface of the body; and
a step of supplying acetylene gas inside the body at a flow rate in a range of 500 to 4000 sccm while maintaining the vacuum level in a range of 1 to 30 Pa inside the body, to generate plasma to deposit the diamond-like carbon coating film on the inner surface of the body.

9. The method of manufacturing the carbon-coated member according to claim 8, further comprising a step of supplying a pulse current in a range of 2 to 100 A to the body for a time in a range of 5 to 200 seconds to apply a bias voltage to the body to convert the acetylene gas into plasma.
